(19) United States
(12) Patent Application Publication
(10) Pub. No.: US 2010/0213513 A1
(43) Pub. Date: Aug. 26, 2010

(54) Hyperabrupt Diode Structure And Method For Making Same

(75) Inventors: Peter J. Zampardi, Newbury Park, CA (US); HsiangChih Sun, Thousand Oaks, CA (US)

Correspondence Address: Smith Frohwein Tempel Greenlee Blaha LLC, Two Ravinia Drive, Suite 700, Atlanta, GA, 30346, US

(73) Assignee: Skyworks Solutions, Inc., Woburn, MA (US)

(21) Appl. No.: 12/393,118

(22) Filed: Feb. 26, 2009

(51) Int. Cl. H01L 29/205; H01L 21/329

(52) U.S. Cl. 257/201; 438/379; 257/E29.091; 257/E21.364

(57) ABSTRACT

A hyperabrupt diode structure includes a substrate formed from a low-ohmic contact material, a graded semiconductor layer comprising gallium arsenide, an offset layer comprising indium gallium phosphide over the graded semiconductor layer, a contact layer comprising gallium arsenide over the offset layer, a first electrical contact on the substrate, the first electrical contact forming a cathode of the hyperabrupt diode structure, and a second electrical contact over the contact layer, the second electrical contact forming an anode of the hyperabrupt diode structure.

### BACKGROUND

A diode is an electrical device that allows current to flow through it in one direction with far greater ease than in the opposite direction. Although a diode can be fabricated using a variety of technologies and materials, the most common kind of diode in modern circuit design is the semiconductor diode. A diode will either allow or prevent current to flow, depending on the polarity of the applied voltage. When the polarity of a voltage source applied to the diode is such that electrons are allowed to flow through the diode, the diode is said to be forward-biased. Conversely, when the voltage source is applied to the diode in the opposite polarity, the diode blocks current, and is said to be reverse-biased. However, a diode may allow a reverse leakage current to flow. A reverse leakage current in a semiconductor diode refers to the current flowing through the semiconductor diode when the diode is reverse biased.

Further, a diode has a point at which a reverse bias voltage will be sufficient to allow substantial current to flow through the diode in the reverse direction. This point is referred to as the breakdown voltage of the diode.

There are a number of different diode types. A varactor diode is a two-terminal device that is designed to provide a voltage-controlled capacitance when operated under reverse bias. A varactor diode includes a PN junction with a positive or P-region with positive ions (also referred to as holes) and a negative or N-region with negative electrons. Applying voltage to the PN junction causes current to flow in only one direction as electrons from the N-region fill “holes” in the P-region. When the junction is reverse-biased, increasing the applied voltage causes the depletion region to widen, increasing the effective distance between the capacitor plates and decreasing the effective capacitance. By adjusting the doping gradient and junction width, the capacitance range can be controlled using reverse voltage. A hyperabrupt varactor diode refers to a diode in which a rapid change in the capacitance of the depletion layer is caused by a change in the applied reverse bias voltage.

Reverse leakage current in a hyperabrupt varactor diode can limit the performance of the diode. Therefore, it is desirable to reduce the reverse leakage current in a hyperabrupt varactor diode.

### SUMMARY

Embodiments of a hyperabrupt diode structure include a substrate formed from a low-ohmic contact material, a graded semiconductor layer comprising gallium arsenide, an offset layer comprising indium gallium phosphide over the graded semiconductor layer, a contact layer comprising gallium arsenide over the offset layer, a first electrical contact on the substrate, the first electrical contact forming a cathode of the hyperabrupt diode structure, and a second electrical contact over the contact layer, the second electrical contact forming an anode of the hyperabrupt diode structure.

Other embodiments are also provided. Other systems, methods, features, and advantages of the invention will be or become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE FIGURES

The invention can be better understood with reference to the following figures. The components within the figures are not necessarily to scale, emphasis instead being placed upon clearly illustrating the principles of the invention. Moreover, in the figures, like reference numerals designate corresponding parts throughout the different views.

FIG. 1 is a schematic diagram illustrating a simplified semiconductor layer structure from which a hyperabrupt diode structure can be fabricated.

FIG. 2 is an energy band diagram of the structure of FIG. 1.

FIG. 3 is a schematic diagram illustrating an embodiment of a varactor diode fabricated using the layer structure of FIG. 1.

FIG. 4 is a schematic diagram illustrating an alternative embodiment of the varactor diode of FIG. 3.

FIG. 5 is a schematic diagram illustrating the doping concentration of the layer structure of FIG. 1.

FIG. 6 is a flow chart describing a method for fabricating an embodiment of the varactor diode of FIG. 3.

### DETAILED DESCRIPTION

Although described with particular reference to a device fabricated in the gallium arsenide (GaAs) material system, the hyperabrupt diode structure described herein can be fabricated using other III-V semiconductor materials, such as indium phosphide (InP) and gallium nitride (GaN). Further, any of a variety of semiconductor growth, formation and processing technologies can be used to form the layers and fabricate the structure or structures that comprise the hyperabrupt diode structure described herein. For example, the semiconductor layers can be formed using molecular beam epitaxy (MBE), metal organic chemical vapor deposition (MOCVD), which is also sometimes referred to as organic metallic vapor phase epitaxy (OMVPE), or any other technique. Moreover, the thicknesses of the various semiconductor layers described below are approximate, and may range to thinner or thicker than that described. Similarly, the doping levels of the doped semiconductor layers described below are approximate.

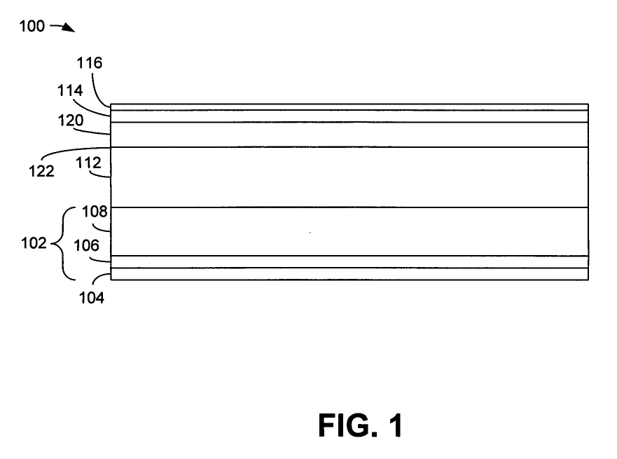

FIG. 1 is a schematic diagram illustrating a simplified semiconductor layer structure from which a hyperabrupt diode structure can be fabricated. The hyperabrupt diode structure 100 comprises a substrate 102 over which a number of other layers are formed. In an embodiment, the substrate 102 can include one or more buffer layers, contact layers, and layers upon which additional semiconductor material layers can be formed. In the example shown in FIG. 1, two buffer layers are shown. A first buffer layer 104 can be fabricated using gallium arsenide (GaAs) and a second buffer layer 106 can be fabricated using aluminum gallium arsenide (AlGaAs), using compositions that are known in the art. The buffer layer 104 can be formed using, for example, a 50 nanometer (nm) thick layer of gallium arsenide. The buffer layer 106 can be formed using, for example, a 50 nm thick layer of aluminum gallium arsenide. The buffer layer 104 and the buffer layer 106 are intrinsic, or undoped.

In an embodiment, the substrate 102 also includes a low-ohmic contact layer 108 located over the buffer layer 106. In an embodiment, the layer 108 can be, for example, formed using gallium arsenide to an approximate thickness of 800 nm or thicker. The layer 108 can be doped n+ to a level of approximately 5×10¹³ atoms per cubic centimeter (cm⁻³). A greater doping concentration is also possible. As known in the art, semiconductors that are doped n-type, or n+, are doped using donor atoms, and semiconductors that are doped p-type, or p+, are doped using acceptor atoms. In an alternative embodiment described below, the buffer layer 106 of aluminum gallium arsenide can function as a selective etch-stop layer to allow etching and metallic contact to the layer 108.

In an embodiment, a semiconductor layer 112 having a graded doping profile is located over the substrate 102. The layer 112 is also referred to as a graded layer 112. In an embodiment, the graded layer 112 is formed using gallium arsenide to a thickness of approximately 900 to 2000 nm. In an embodiment, the graded layer is doped n-type using, for example, a silicon dopant. The doping profile of the graded layer 112 varies from approximately 8.15×10¹⁵ atoms per cm⁻³ proximate to the layer 108, to a doping level of approximately 3.85×10¹⁷ atoms per cm⁻³ distal from the layer 108. However, doping levels greater or less than those described herein are possible.

In accordance with an embodiment of the hyperabrupt diode structure 100, an offset layer 120 is located over the graded layer 112. In some embodiments, the offset layer 120 may be referred to as a setback layer. In this example, the offset layer 120 is formed using indium gallium phosphide (InGaP), to a thickness of approximately 100 to 200 nm. In an embodiment, the mole fraction, also referred to as the molar composition, of the offset layer 120 is In_{0.51}Ga_{0.49}P, and the offset layer 120 is doped n+ to a level of approximately 1×10¹⁶ atoms per cm⁻³. However, other compositions are possible.

A layer 114 of gallium arsenide is located over the offset layer 120. The layer 114 can be formed using gallium arsenide to an approximate thickness of 90 nm. The layer 114 can be doped p++ to approximately 4×10¹⁹ atoms per cm⁻³ using, for example, a carbon or beryllium dopant. The layer 114 provides a contact layer for an electrode, the formation of which will be described below.

A layer 116 of indium gallium phosphide can be located over the layer 114. The layer 116 can be formed using indium gallium phosphide to an approximate thickness of 40 nm. The layer 116 can be doped p+ to a concentration of approximately 3×10¹⁷ atoms per cm⁻³. The layer 116 provides a passivation layer over the layer 114. Portions of the layer 116 will be removed where it is desirable to make electrical contact to the layer 114. However, portions of the layer 116 that are left intact over the layer 114 can further reduce leakage current at the surface of the layer 114.

In accordance with an embodiment of the hyperabrupt diode structure, the indium gallium phosphide of the offset layer 120 has a relatively large bandgap difference with respect to the bandgap of the graded layer 112 and the bandgap of the contact layer 114. Further, the offset layer 120 has a relatively low conduction band offset and a relatively high valence band offset. The bandgap difference between the indium gallium phosphide and the gallium arsenide significantly reduce reverse current leakage. The bandgap difference between the indium gallium phosphide and the gallium arsenide results in lower recombination current and also provides a higher critical breakdown field in the offset layer 120 composed of indium gallium phosphide, than in the gallium arsenide of the graded layer 120 and the contact layer 114. A higher critical breakdown field, also referred to as the critical breakdown voltage under reverse bias, is advantageous because it allows the diode structure to have superior electrical characteristics over a wide range of operating voltages. Further, the relatively low conduction band offset and a relatively high valence band offset of the indium gallium phosphide also help to reduce current leakage.

As will be described below, the bandgap of the gallium arsenide material that forms the graded layer 112 and the contact layer 114 is approximately 1.42 electron volts (eV). However, the bandgap of the indium gallium phosphide material that forms the offset layer 120 is approximately 1.85 to 1.89 eV. This energy difference between the graded layer 112, the contact layer 114, and the offset layer 120 creates a bandgap offset in the range of approximately 0.43 to 0.47 eV between the graded layer 112, the contact layer 114 and the offset layer 120. Further, at the junction 122 between the contact layer 114 and the offset layer 120, the conduction band offset (ΔEc) is approximately 0.1 eV, and the valence band offset (ΔEv) is approximately 0.37 eV. The presence of the offset layer 120 helps to reduce leakage current through the structure 100 under reverse bias. Alternatively, other wide bandgap materials, such as, for example only, aluminum gallium arsenide (AlGaAs) or indium gallium aluminum phosphide (AlGaAlP) can be used to fabricate the offset layer 120.

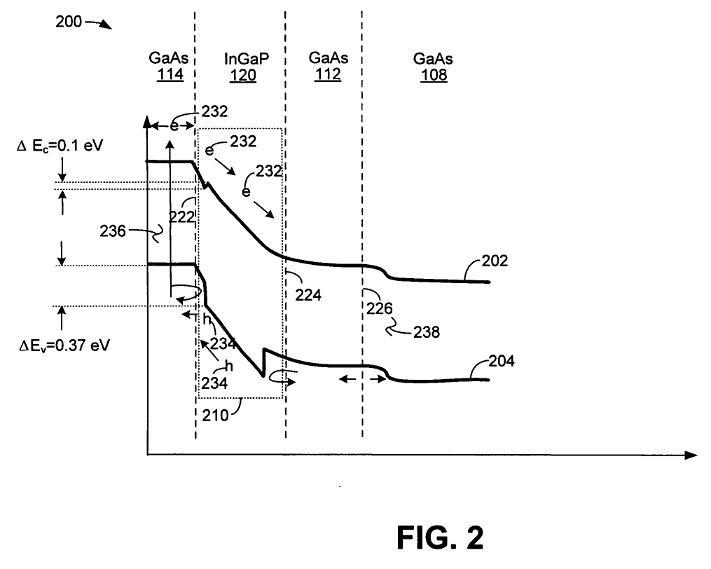

FIG. 2 is an energy band diagram of the structure of FIG. 1. The energy band diagram 200 includes a trace 202 representing the conduction band and a trace 204 representing the valence band. The cathode, which is formed by an electrical contact to the low-ohmic layer 108 (FIG. 1), is shown on the right-hand side of the drawing while the anode, which is formed by an electrical contact to the contact layer 114 (FIG. 1) is shown on the left-hand side of the drawing. As illustrated in FIG. 2, the conduction band offset, ΔE_{c}, at the junction 222 between the offset layer 120 and the contact layer 114 is approximately 0.1 eV. However, the valence band offset, ΔEᵥ, at the junction 222 between the offset layer 120 and the contact layer 114 is approximately 0.37 eV. The energy difference between the conduction band and the valence band at the junction 222, and the approximate bandgap difference of approximately 0.43 to 0.47 eV between the indium gallium phosphide in the offset layer 120 and the gallium arsenide in the contact layer 114, reduces space charge recombination in the offset layer 120. Further, the depletion region, which is illustrated in FIG. 2 using the dotted line 210, can vary depending on the reverse bias voltage applied to the hyperabrupt diode structure modeled by the energy band diagram of FIG. 2.

Electrons 232 in the gallium arsenide of the contact layer 114 can go to either the anode 236 or the cathode 238. Electrons 232 and holes 234 in the indium gallium phosphide material forming the layer 120 are separated by a field where a lower absorption coefficient prevents current from flowing. Holes 234 at the interface 226 between the layer 108 and the layer 112 cannot go toward the anode 236, but must instead go toward the cathode 238, which is blocked. Therefore, leakage current at the junction 222 between the offset layer 120 and the contact layer 114 is reduced.

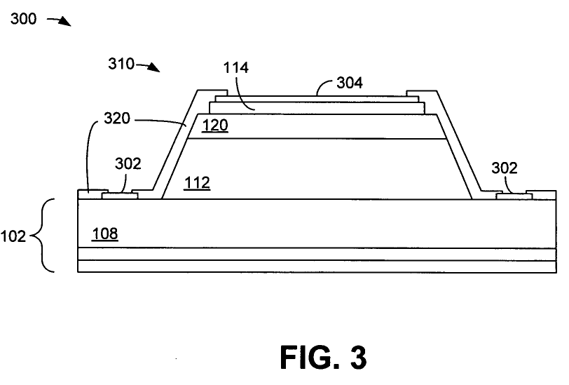

FIG. 3 is a schematic diagram illustrating an embodiment of a varactor diode 300 fabricated using the layer structure of FIG. 1. The varactor diode 300 is fabricated by forming portions of the graded layer 112, offset layer 120 and contact layer 114 (FIG. 1) into a mesa structure 3 10. The mesa structure 310 can be created in a variety of ways known to those skilled in the art, such as, for example, by milling, etching, or other techniques. A metal contact 302 is formed on the low-ohmic layer 108 and forms the cathode 238 (FIG. 2) of the varactor diode 310. Portions of the passivation layer 116 are removed and another metal contact 304 is formed on the contact layer 114 and forms the anode 236 of the varactor diode 300. An additional passivation material 320 is applied over the mesa structure and over the exposed portions of the low-ohmic contact layer 108 to protect the varactor diode. In an embodiment, the passivation material can be silicon nitride having a composition of Si₃N₄, or other materials or compositions.

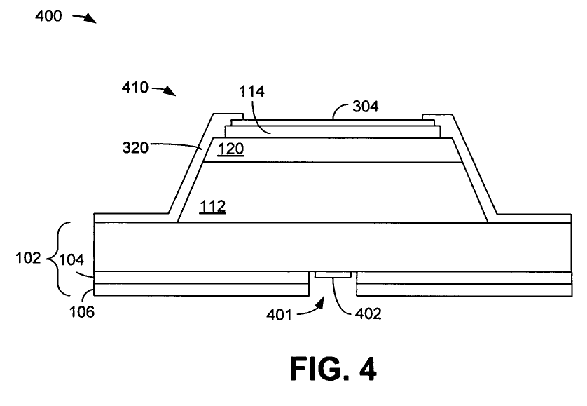

FIG. 4 is a schematic diagram illustrating an alternative embodiment 400 of the varactor diode of FIG. 3. As shown in FIG. 4, portions of the buffer layer 104 and the buffer layer 106 are selectively etched to form an opening 401, through which access to the backside of the low-ohmic layer 108 is provided. The buffer layer 106 of aluminum gallium arsenide can function as a selective etch-stop layer to allow etching through the buffer layers 104 and 106 to the low-ohmic layer 108. A metal contact 402 is formed on the low-ohmic layer 108 and forms the cathode 238 (FIG. 2) of the varactor diode 400.

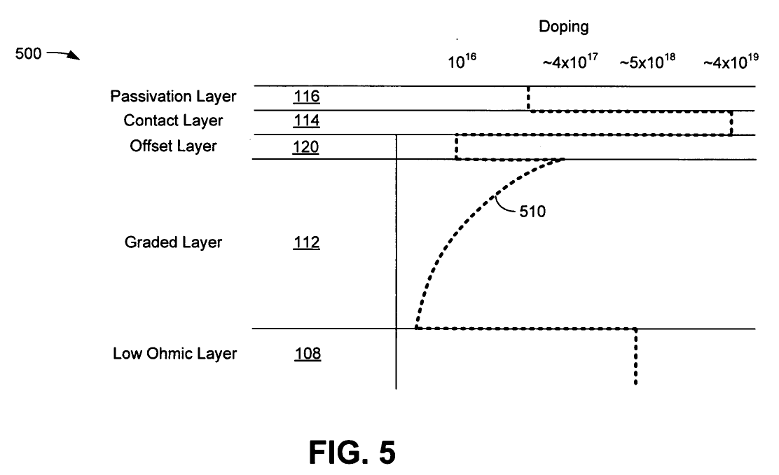

FIG. 5 is a schematic diagram illustrating the doping concentration of the layer structure of FIG. 1. The doping concentrations shown in FIG. 5 are approximations. The doping concentration generally ranges between 1×10¹⁶ and approximately 4×10¹⁹ atoms per cm⁻³. The doping level peaks at approximately 4×10¹⁷ atoms per cm⁻³ in the portion of the graded layer 112 that is near the junction 222 between the graded layer 112 and the offset layer 120, as shown using trace 510. The doping in the offset layer 120 is at approximately 1×10¹⁶ atoms per cm⁻³. The doping in the contact layer 114 is approximately 4×10¹⁹ atoms per cm⁻³ and the doping in the passivation layer 116 is approximately 3×10¹⁷ atoms per cm⁻³ to further reduce surface leakage wherever metal contact is not formed.

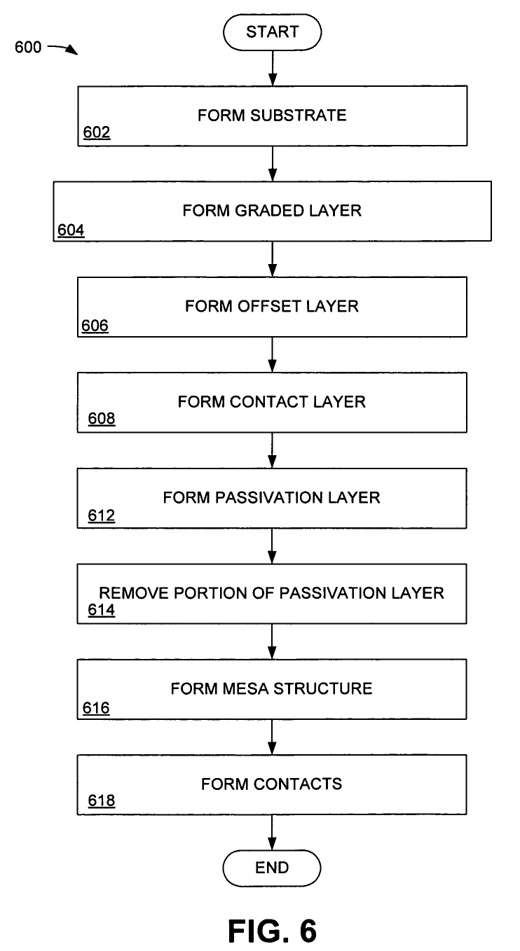

FIG. 6 is a flow chart describing a method for fabricating an embodiment of the varactor diode of FIG. 3. In block 602, a substrate layer of gallium arsenide, or variations of materials in the gallium arsenide material system, is formed. The substrate layer may comprise a single layer or multiple layers, including buffer layers, as described above. In an embodiment, the substrate includes a first buffer layer 104 of gallium arsenide and a second buffer layer 106 of aluminum gallium arsenide. The first buffer layer 104 can be, for example, a 50 nanometer (nm) thick layer of gallium arsenide. The second buffer layer 106 can be, for example, a 50 nm thick layer of aluminum gallium arsenide. The buffer layer 104 and the buffer layer 106 are intrinsic, or undoped. The substrate also includes a low-ohmic contact layer 108 formed over the buffer layer 106. The layer 108 can be, for example, an approximate 800 nm thick, or thicker, layer of gallium arsenide. The layer 108 can be doped n+ to a level of approximately 5×10¹⁸ atoms per cm⁻³ or greater.

In block 604, a graded layer 112 is formed over the substrate. The graded layer 112 can be, for example, a layer of semiconductor material doped to have a graded doping profile. In an embodiment, the graded layer 112 is gallium arsenide and is formed to a thickness of approximately 900 to 2000 nm. In an embodiment, the doping profile of the graded layer 112 varies from approximately 8.15×10¹⁵ atoms per cm⁻³ proximate to the layer 108, to a doping level of approximately 3.85×10¹⁷ atoms per cm⁻³ distal from the layer 108. However, doping levels greater or less than those described herein are possible.

In block 606, an offset layer 120 is formed over the graded layer 112. In some embodiments, the offset layer 120 may be referred to as a setback layer. In this example, the offset layer 120 is formed using indium gallium phosphide (InGaP), to a thickness of approximately 100-200 nm. In an embodiment, the mole fraction of the offset layer 120 is In_{0.51}Ga_{0.49}P, and the offset layer 120 is doped n-type to a level of approximately 1×10¹⁶ atoms per cm⁻³.

In block 608, a layer 114 of gallium arsenide is formed over the offset layer 120. The layer 114 can be formed using gallium arsenide to an approximate thickness of 90 nm. The layer 114 can be doped to approximately 4×10¹⁹ atoms per cm⁻³. The layer 114 provides a contact layer for an electrode, the formation of which will be described below.

In block 612, a passivation layer 116 is formed over the contact layer 114. The passivation layer 116 can be formed using indium gallium phosphide to an approximate thickness of 40 nm. The passivation layer 116 can be doped p+ to approximately 3×10¹⁷ atoms per cm⁻³.

In block 614, portions of the passivation layer 116 are removed where it is desirable to make electrical contact to the layer 114. However, portions of the layer 116 that are left intact over the layer 114 can further reduce leakage current at the surface of the layer 114.

In block 616, portions of the graded layer 112, offset layer 120 and contact layer 114 are formed into a mesa structure 310. In block 618, electrical contacts are formed over exposed portions of the low-ohmic contact layer 108 and the contact layer 114. Optionally, a passivation material 320 is applied over the mesa structure 310 and over the exposed portions of the low-ohmic contact layer 108 to protect the varactor diode.

While various embodiments of the invention have been described, it will be apparent to those of ordinary skill in the art that many more embodiments and implementations are possible that are within the scope of the invention. For example, the invention is not limited to the gallium arsenide material system.

What is claimed is:

1. A hyperabrupt diode structure, comprising:
a substrate formed from a low-ohmic contact material;
a graded semiconductor layer comprising gallium arsenide;
an offset layer comprising indium gallium phosphide over the graded semiconductor layer;
a contact layer comprising gallium arsenide over the offset layer;
a first electrical contact on the substrate, the first electrical contact forming a cathode of the hyperabrupt diode structure; and
a second electrical contact over the contact layer, the second electrical contact forming an anode of the hyperabrupt diode structure.

2. The hyperabrupt diode structure of claim 1, in which:
the substrate is gallium arsenide;
the graded semiconductor layer comprising gallium arsenide has a doping ranging from approximately 1×10¹⁶ atoms per cm⁻³ proximate to the substrate to approximately 4×10¹⁷ atoms per cm⁻³ distal from the substrate; and
the offset layer comprising indium gallium phosphide has a doping level of at least 1×10¹⁶ atoms per cm⁻³.

3. The hyperabrupt diode structure of claim 1, wherein the offset layer has a bandgap difference of approximately 0.43 to 0.47 electron volts (eV) with respect to the contact layer and the graded semiconductor layer.

4. The hyperabrupt diode structure of claim 3, wherein at an interface between the contact layer and the offset layer, the offset layer creates an energy offset in a conduction band that is lower than an energy offset in a valence band to reduce leakage current in the hyperabrupt diode structure.

5. The hyperabrupt diode structure of claim 4, in which the energy offset in the conduction band is approximately 0.1 eV and the energy offset in the valence band is approximately 0.37 eV.

6. The hyperabrupt diode structure of claim 4, in which the offset layer is composed of In_{0.51}Ga_{0.49}P.

7. The hyperabrupt diode structure of claim 4, in which the first electrical contact is formed on the low-ohmic contact material through at least one buffer layer.

8. A semiconductor material structure, comprising:
a substrate formed from a low-ohmic contact material;
a graded semiconductor layer;
an offset layer formed over the graded semiconductor layer;
a contact layer formed over the offset layer; and
wherein the offset layer is formed from a semiconductor material having a bandgap difference of approximately 0.43 to 0.47 electron volts (eV) with respect to the graded semiconductor layer and the contact layer.

9. The semiconductor material structure of claim 8, in which:
the substrate is gallium arsenide;
the graded semiconductor layer is gallium arsenide;
the offset layer is chosen from indium gallium phosphide, aluminum gallium arsenide, and indium gallium aluminum phosphide; and
the contact layer is gallium arsenide.

10. The semiconductor material structure of claim 9, wherein at an interface between the contact layer and the offset layer, the offset layer creates an energy offset in a conduction band that is lower than an energy offset in a valence band to reduce leakage current in the semiconductor material structure.

11. The semiconductor material structure of claim 10, in which the energy offset in the conduction band is approximately 0.1 eV and the energy offset in the valence band is approximately 0.37 eV.

12. The semiconductor material structure of claim 11, in which the offset layer is composed of In_{0.51}Ga_{0.49}P.

13. A method for making a hyperabrupt varactor diode, comprising:
forming a substrate from a low-ohmic contact material;
forming a graded semiconductor layer comprising gallium arsenide having graded doping over the substrate;
forming an offset layer comprising indium gallium phosphide over the graded semiconductor layer;
forming a contact layer comprising gallium arsenide over the offset layer;
forming a first electrical contact on the substrate, the first electrical contact forming a cathode of the hyperabrupt diode structure; and
forming a second electrical contact over the contact layer, the second electrical contact forming an anode of the hyperabrupt diode structure.

14. The method of claim 13, further comprising:
forming the substrate of gallium arsenide;
doping the graded semiconductor layer comprising gallium arsenide to a range of approximately 1×10¹⁶ atoms per cm⁻³ proximate to the substrate to approximately 4×10¹⁷ atoms per cm⁻³ distal from the substrate; and
doping the offset layer comprising indium gallium phosphide to a doping level of at least 1×10¹⁶ atoms per cm⁻³.

15. The method of claim 13, wherein the offset layer has a bandgap difference of approximately 0.43 to 0.47 electron volts (eV) with respect to the contact layer.

16. The method of claim 15, wherein at an interface between the contact layer and the offset layer, the offset layer creates an energy offset in a conduction band that is lower than an energy offset in a valence band to reduce leakage current in the hyperabrupt diode structure.

17. The method of claim 16, in which the energy offset in the conduction band is approximately 0.1 eV and the energy offset in the valence band is approximately 0.37 eV.

18. The method of claim 16, in which the offset layer is formed of In_{0.51}Ga_{0.49}P.
